(19) United States
(12) Patent Application Publication
(10) Pub. No.: US 2026/0369857 A1
(43) Pub. Date: Nov. 19, 2026

(54) TRANSMISSION LINE STRUCTURE AND ANTENNA MODULE

(71) Applicant: Murata Manufacturing Co., Ltd., Nagaokakyo-shi (JP)

(72) Inventors: Daisuke DOI, Nagaokakyo-shi (JP); Hirotsugu MORI, Nagaokakyo-shi (JP); Kengo ONAKA, Nagaokakyo-shi (JP)

(73) Assignee: Murata Manufacturing Co., Ltd., Nagaokakyo-shi (JP)

(21) Appl. No.: 19/723,033

(22) Filed: Jun. 29, 2026

Related U.S. Application Data
(63) Continuation of application No. PCT/JP2025/000860, filed on Jan. 14, 2025.

(30) Foreign Application Priority Data
Feb. 5, 2024 (JP) 2024-015593

(51) Int. Cl. H01P 3/08; H01Q 9/04

(52) U.S. Cl. CPC H01P 3/08; H01Q 9/045

(57) ABSTRACT

A transmission line structure includes a dielectric substrate having opposite first and second surfaces, a ground electrode between the first and second surfaces, a first transmission line extending in a first direction and being closer to the first surface than to the ground electrode, a ground pad at the first surface, a first signal coupled to an end portion of the first transmission line, at least one interlayer connector inside the dielectric substrate and coupling the ground electrode to the ground pad, and a connector on the first main surface and coupling the ground pad to the first signal pad, wherein the ground pad has a rectangular shape including a short side in the first direction and a long side in a second direction, and wherein a length of the ground pad in the first direction is shorter than a length of the connector in the first direction.

### CROSS-REFERENCE TO RELATED APPLICATIONS

This application is a continuation of PCT Application No. PCT/JP2025/000860, filed on Jan. 14, 2025, which claims priority to Japanese Patent Application No. 2024-015593, filed on Feb. 5, 2024. The entire contents of each of the above-listed applications are incorporated herein by reference.

### TECHNICAL FIELD

The present disclosure relates to a transmission line structure and an antenna module including a transmission line structure and an antenna substrate.

### BACKGROUND ART

International Publication No. 2022/038879 (Patent Document 1) discloses an antenna module provided with a transmission line structure including a transmission line to transmit a radio-frequency signal and a ground electrode.

### CITATION LIST

### Patent Document

Patent Document 1: International Publication No. 2022/038879

### SUMMARY

According to an aspect of the present disclosure, a transmission line structure includes a dielectric substrate having a flat-plate shape, the dielectric substrate including a first main surface and a second main surface opposed to the first main surface, a ground electrode between the first main surface and the second main surface, a first transmission line disposed closer to the first main surface than to the ground electrode, the first transmission line extending in a first direction, a ground pad provided to the first main surface, a first signal coupled to an end portion of the first transmission line, the first signal pad being at the first main surface, at least one interlayer connector inside the dielectric substrate, the at least one interlayer connector being coupled to the ground electrode and the ground pad, and a connector on the first main surface, the connector being coupled to the ground pad and the first signal pad, wherein the ground pad has a rectangular shape including a long side and a short side, the long side extending in a second direction approximately perpendicular to the first direction, and the short side extending in the first direction, and wherein a length of the ground pad in the first direction is shorter than a length of the connector in the first direction.

### BRIEF DESCRIPTION OF DRAWINGS

FIG. 1 is a diagram illustrating an antenna module according to Embodiment 1.

FIG. 2 is a perspective view of a transmission line structure according to Embodiment 1.

FIG. 3 is a plan view of the transmission line structure according to Embodiment 1.

FIG. 4 is a certain sectional view of the transmission line structure according to Embodiment 1.

FIG. 5 is a diagram illustrating a connector according to Embodiment 1.

FIG. 6 is a plan view of a transmission line structure according to Embodiment 2.

FIG. 7 is a certain sectional view of the transmission line structure according to Embodiment 2.

FIG. 8 is a plan view of a transmission line structure according to Embodiment 3.

FIG. 9 is a plan view of a transmission line structure according to Embodiment 4.

### DESCRIPTION OF EMBODIMENTS

When a transmission line structure including a transmission line and a ground electrode is coupled to another substrate, a connector may be used. In the case in which the transmission line structure including the connector is used, the transmission line structure may be used in a bent manner depending on an application. However, in International Publication No. 2022/038879 (Patent Document 1), in the transmission line structure including the transmission line and the ground electrode, a connection part of the connector is not devised and a thickness of the transmission line structure is thick. Therefore, the transmission line structure is not suitable for use in a bent manner.

In contrast, the present disclosure provides a transmission line structure suitable for use in a bent manner.

Hereinafter, embodiments of the present disclosure are described in detail with reference to the drawings. Note that the same or corresponding parts in the drawings are denoted by the same reference characters to omit redundant description.

### Embodiment 1

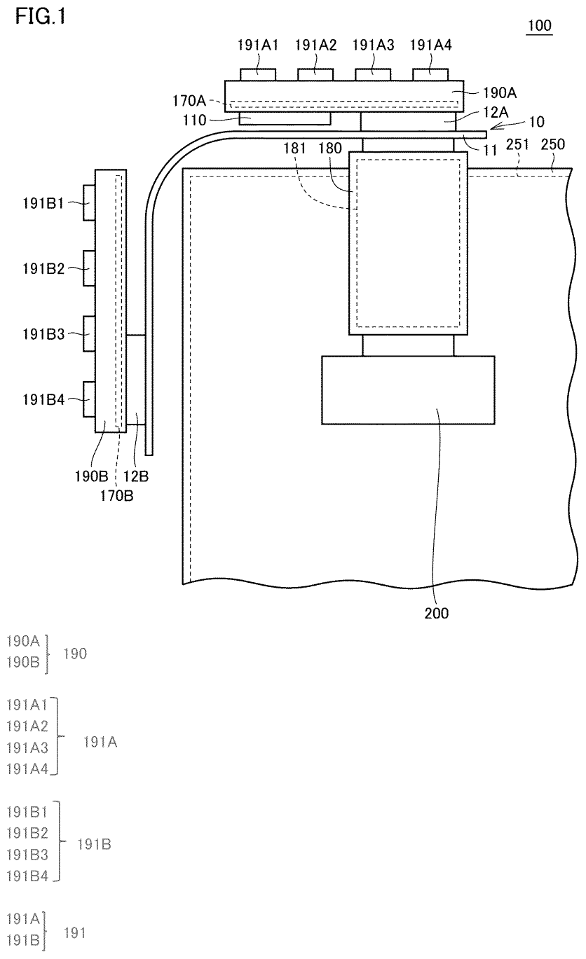

FIG. 1 is a diagram illustrating an antenna module 100 according to Embodiment 1. For example, the antenna module 100 is used in a mobile terminal such as a cellular phone, a smartphone, or a tablet, a personal computer having a communication function, and the like. An example of a frequency band of radio waves used for the antenna module 100 according to Embodiment 1 is a millimeter-wave band having a center frequency of 28 GHz, 39 GHz, 60 GHz, or the like, but radio waves in frequency bands other than the above are also applicable.

The antenna module 100 includes a radio frequency integrated circuit (i.e., an RFIC 110), an antenna device 190A including radiation electrodes 191A1 to 191A4, an antenna device 190B including radiation electrodes 191B1 to 191B4, a transmission line structure 10, and connectors 12A and 12B. The RFIC 110 supplies a radio-frequency signal. The antenna device 190A is coupled to the transmission line structure 10 via the connector 12A. The antenna device 190B is coupled to the transmission line structure 10 via the connector 12B. The RFIC 110 may include a system in package (SiP) structure including peripheral components such as a PMIC (power management IC) as a set.

Below, the antenna devices 190A and 190B are also collectively referred to as an “antenna device 190”. The radiation electrodes 191A1 to 191A4 are also collectively referred to as a “radiation electrode 191A”. The radiation electrodes 191B1 to 191B4 are also collectively referred to as a “radiation electrode 191B”. The radiation electrodes 191A and 191B are also collectively referred to as a “radiation electrode 191”.

The antenna device 190A is coupled to a baseband integrated circuit (i.e., BBIC 200) via a connection member 180. The antenna device 190B is coupled to the antenna device 190A by the transmission line structure 10. The BBIC 200 is mounted on a motherboard 250 and forms a baseband signal processing circuit. The BBIC 200 is electrically coupled to the RFIC 110.

Signals transmitted from the BBIC 200 to the antenna module 100 are radiated from the antenna devices 190A and 190B. Signals received by the antenna devices 190A and 190B are processed in the BBIC 200.

The motherboard 250 is a flat-plate-shaped printed circuit board on which a plurality of components including the BBIC 200 are mounted. The motherboard 250 includes, for example, an MLB (multilayerboard). A ground electrode 251 is provided to a mounting surface of the motherboard 250. The ground electrode 251 is disposed in such a manner as to be widely attached to the entire mounting surface of the motherboard 250. The ground electrode 251 may be provided only to a part of the mounting surface of the motherboard 250. The ground electrode 251 may be provided to the inside of the motherboard 250 instead of a surface layer of the mounting surface of the motherboard 250.

A dielectric substrate included in the antenna device 190 is, for example, a low temperature co-fired ceramics (LTCC) multilayer substrate, a multilayer resin substrate formed in such manner that multiple resin layers including a resin such as epoxy or polyimide are stacked, a multilayer resin substrate formed in such a manner that multiple resin layers including liquid crystal polymer (LCP) with a lower dielectric constant are stacked, a multilayer resin substrate formed in such a manner that multiple resin layers including fluororesin or a PET (polyethylene terephthalate) material are stacked, or a ceramic multilayer substrate other than LTCC. Note that the dielectric substrate included in the antenna device 190 does not necessarily have a multilayer structure, but may be a single-layer substrate.

The radiation electrode 191 is made of a flat-plate-shaped conductor such as copper or aluminum. A shape of the radiation electrode 191 is not limited to a rectangle, but may be a polygon, a circle, an ellipse, or a cross shape. The radiation electrode 191 is provided to a surface or an internal layer of the dielectric substrate.

In FIG. 1, an array antenna in which four radiation electrodes 191 are arranged in one direction is illustrated, but a single radiation electrode 191 may be included, or multiple radiation electrodes may be arranged one-dimensionally or two-dimensionally.

A ground electrode 170A is disposed inside the dielectric substrate of the antenna device 190A to be opposed to the radiation electrode 191A. A ground electrode 170B is disposed inside the dielectric substrate of the antenna device 190B to be opposed to the radiation electrode 191B.

A radio-frequency signal from the RFIC 110 is supplied to the radiation electrode 191A of the antenna device 190A. A radio-frequency signal from the RFIC 110 is supplied to the radiation electrode 191B of the antenna device 190B via the transmission line structure 10. When a radio-frequency signal is supplied to the antenna device 190A, a radio wave is radiated from the radiation electrode 191A, and a radio wave is not radiated from the radiation electrode 191B. Conversely, when a radio-frequency signal is supplied to the antenna device 190B, a radio wave is radiated from the radiation electrode 191B, and a radio wave is not radiated from the radiation electrode 191A. The antenna device 190A and the antenna device 190B radiate radio waves in different directions.

The connection member 180 is a flat-plate-shaped flat cable. The connection member 180 is disposed in such a manner that a back surface of the connection member 180 is in contact with the mounting surface of the motherboard 250. The connection member 180 includes a ground electrode 181 therein. The connection member 180 includes a plurality of power supply wires therein. The connection member 180 includes a dielectric substrate made of ceramics such as LTCC and resin. The connection member 180 may be made of a flexible material, or may be made of a rigid material that does not deform. Conductive members such as the power supply wire and the ground electrode 181 included in the connection member 180 are coupled to the antenna device 190 and the motherboard 250 by detachable connectors or by solder.

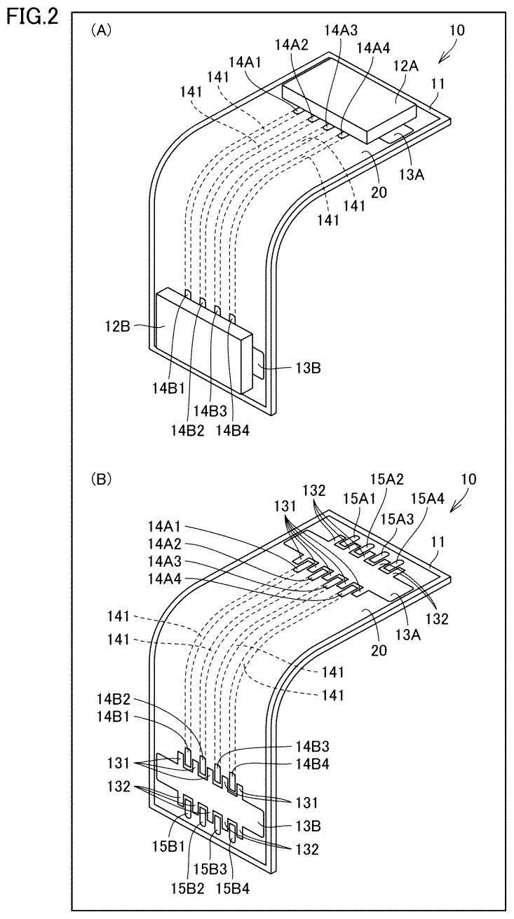

Next, the transmission line structure 10 will be described with reference to FIGS. 2 to 4. FIG. 2 is a perspective view of the transmission line structure 10 according to Embodiment 1. The transmission line structure 10 illustrated in FIG. 2 is in a bent state. Part (A) of FIG. 2 is a diagram illustrating a state in which the connectors 12A and 12B are attached to the transmission line structure 10. Part (B) of FIG. 2 is a diagram illustrating a state in which the connectors 12A and 12B are removed from the transmission line structure 10.

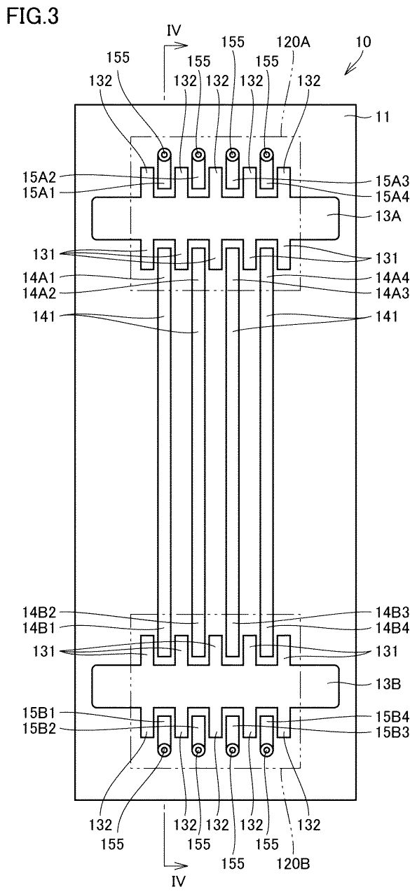

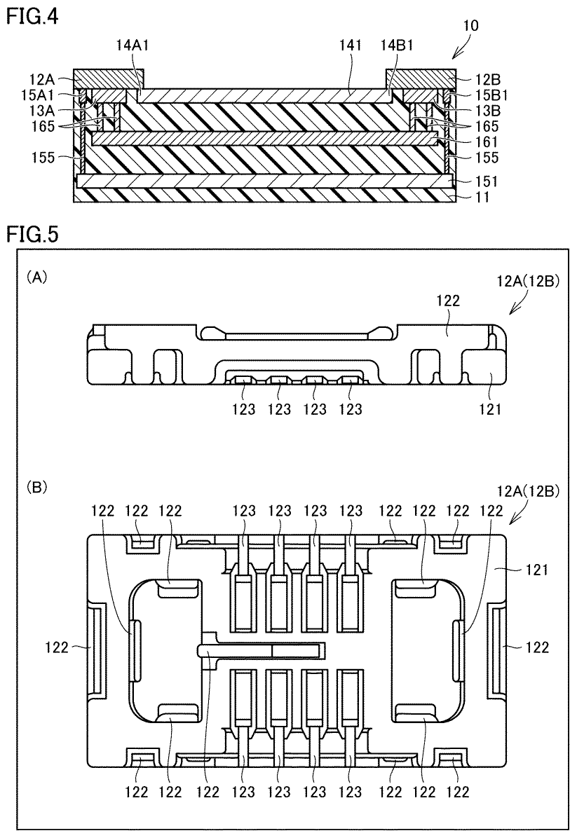

FIG. 3 is a plan view of the transmission line structure 10 according to Embodiment 1. The transmission line structure 10 illustrated in FIG. 3 is a straightened state. FIG. 4 is a certain sectional view of the transmission line structure 10 according to Embodiment 1. FIG. 4 is a partial sectional view taken along line IV-IV in FIG. 3. Note that the certain sectional view in FIG. 4 is schematic illustration where a thickness in a layer direction is larger than an actual thickness.

The transmission line structure 10 includes a dielectric substrate 11, the connectors 12A and 12B, transmission lines 141 and 151, ground pads 13A and 13B, signal pad members 14A1 to 14A4, 14B1 to 14B4, 15A1 to 15A4, and 15B1 to 15B4, a ground electrode 161, ground vias 165, signal vias 155, and a protection member 20.

The dielectric substrate 11 has a flexible structure as illustrated in FIG. 2. As long as the dielectric substrate 11 has a flexible structure, the dielectric substrate 11 may be made of a material similar to the material of the dielectric substrate included in the antenna device 190 described above. As illustrated in FIG. 3, the dielectric substrate 11 is a substrate in a flat-plate shape including a second main surface opposed to a first main surface, where the side on which the connectors 12A and 12B are disposed is defined as the first main surface (e.g., the first main surface faces the connectors 12A and 12B).

The ground electrode 161 is disposed between the first main surface and the second main surface of the dielectric substrate 11. The ground electrode 161 is electrically coupled to a ground pad at the first main surface by the ground vias 165 as multiple interlayer connectors.

The transmission line 141 is disposed closer to the first main surface with respect to the ground electrode 161 and extends (e.g., lengthwise) in a first direction that is a longitudinal direction of the dielectric substrate 11. For example, the transmission line 141 may be disposed inside the dielectric substrate 11 at a position between the first main surface and the ground electrode 161, such that a distance between the transmission line 141 and the first main surface may be smaller than a distance between the transmission line 141 and the ground electrode 161 (e.g., the distance between the transmission line 141 and the first main surface may be zero). Note that, in FIGS. 3 and 4, the transmission line 141 is illustrated on the first main surface. A resist, which is the protection member 20 illustrated in FIG. 2, is omitted in FIGS. 3 and 4.

The transmission line 141 is a line to transmit a radio-frequency signal and includes four lines as illustrated in FIGS. 2 and 3. As illustrated in FIGS. 2 to 4, one end (e.g., a first end) of the transmission line 141 functions as the signal pad members 14A1 to 14A4 for electrical coupling with the connector 12A. The other end (e.g., a second end opposite the first end) of the transmission line 141 functions as the signal pad members 14B1 to 14B4 for electrical coupling with the connector 12B. The signal pad members 14A1 to 14A4 and the signal pad members 14B1 to 14B4 are also collectively referred to as a first signal pad.

The transmission line 151 is disposed closer to the second main surface with respect to the ground electrode 161 and extends in the first direction, which is the longitudinal direction of the dielectric substrate 11 (e.g., the transmission line 151 is disposed between the second main surface and the ground electrode 161). The transmission line 151 is, similarly to the transmission line 141, a line to transmit a radio-frequency signal and includes four lines, but illustration thereof is omitted except for the certain sectional view illustrated in FIG. 4.

One end (e.g., a first end) of the transmission line 151 is coupled to the signal pad members 15A1 to 15A4 for electrical coupling with the connector 12A via the signal vias 155 extending in a thickness direction of the dielectric substrate 11. The other end (e.g., a second end) of the transmission line 151 is coupled to the signal pad members 15B1 to 15B4 for electrical coupling with the connector 12B via the signal vias 155 extending in the thickness direction of the dielectric substrate 11. The signal pad members 15A1 to 15A4 and the signal pad members 15B1 to 15B4 are also collectively referred to as a second signal pad.

A frequency band of a signal transmitted to the transmission line 141 is higher than a frequency band of a signal transmitted to the transmission line 151. This is because a signal in a higher frequency band has larger loss due to distance than a signal in a lower frequency band, and thereby the transmission line 141 having a higher signal frequency band than the transmission line 151 is disposed closer to the connectors 12A and 12B (than the transmission line 151 is) to shorten transmission distance. Accordingly, the transmission line 141 can have reduced signal loss.

The transmission line 141 is provided to (e.g., formed at or exposed through) the first main surface of the dielectric substrate 11, which is a surface for mounting the connectors 12A and 12B. Accordingly, unlike the transmission line 151, the transmission line 141 is coupled to the connectors 12A and 12B without intervention of the signal vias 155 (e.g., the transmission line 141 may be coupled directly to the connectors 12A and 12B), and thereby impedance matching with a member coupled to the transmission line 141 can be easier.

The transmission line structure 10 has a structure in which one layer of the ground electrode 161 is disposed between the transmission line 141 and the transmission line 151 in the thickness direction of the dielectric substrate 11. The transmission line structure 10 has the ground electrode 161 between the transmission line 141 and the transmission line 151, thus forming a stripline. In this way, the transmission line structure 10 includes a single layer of the ground electrode 161, and thereby the transmission line structure 10 can have a smaller height in the thickness direction as compared with a structure including a plurality of layers of ground electrodes.

The connector 12A is electrically coupled to the ground pad 13A, the first signal pad (signal pad members 14A1 to 14A4), and the second signal pad (signal pad members 15A1 to 15A4) on the first main surface side of the dielectric substrate 11. For example, referring to FIG. 4, first main surfaces of the ground pad 13A, the first signal pad (signal pad members 14A1 to 14A4), and the second signal pad (signal pad members 15A1 to 15A4) may face a same direction, and may be coplanar with each other, such that the connector 12A may be directly on the first main surfaces of the ground pad 13A, the first signal pad (signal pad members 14A1 to 14A4), and the second signal pad (signal pad members 15A1 to 15A4). A position where the connector 12A, illustration of which is omitted in FIG. 3, is disposed is on a line indicated by an outer edge 120A.

The connector 12B is electrically coupled to the ground pad 13B, the first signal pad (signal pad members 14B1 to 14B4), and the second signal pad (signal pad members 15B1 to 15B4) on the first main surface side of the dielectric substrate 11. The structure of the connector 12B may be substantially the same as that of the connector 12A. A position where the connector 12B, illustration of which is omitted in FIG. 3, is disposed is on a line indicated by an outer edge 120B.

The ground pad 13A, 13B has a rectangular shape having a long side in a second direction approximately perpendicular to the first direction, which is the longitudinal direction of the dielectric substrate 11, and a short side in the first direction (e.g., the ground pad 13A, 13B may extend lengthwise perpendicularly to the longitudinal direction of the first transmission line 141). A dimension (e.g., a length) of the ground pad 13A, 13B in the first direction is shorter than a dimension (e.g., a length) of the connector 12A, 12B in the first direction. That is, in the transmission line structure 10, the length of the ground pad 13A, 13B in the first direction, in which the transmission line 141, 151 extends lengthwise, is shorter than the dimension of the connector 12A, 12B, and a contact area between the ground pad 13A, 13B and the connector 12A, 12B is small. Accordingly, when the transmission line structure 10 is bent (e.g., to overlap two different surfaces that are perpendicular to each other), a force applied to the connection part between the ground pad 13A, 13B and the connector 12A, 12B can be reduced, and the transmission line structure 10 can be easily bent. For example, when the connector 12A, 12B and the ground pad 13A, 13B are stacked along a normal direction with respect to a surface of the transmission line structure 10 (e.g., with respect to a longitudinal direction of the transmission line 141), and the same surface of the transmission line structure 10 is bent and extends continuously to overlap two different surfaces that are perpendicular to each other, a force applied to the connection part between the ground pad 13A, 13B and the connector 12A, 12B can be reduced due to the small area therebetween.

For example, referring to FIG. 4, the ground pad 13A may be provided to the first main surface (e.g., the ground pad 13A may be on or exposed through) the first main surface. The ground pad 13A is disposed between the first signal pad (signal pad members 14A1 to 14A4) and the second signal pad (signal pad members 15A1 to 15A4) in the first direction. The ground pad 13B is disposed between the first signal pad (signal pad members 14B1 to 14B4) and the second signal pad (signal pad members 15B1 to 15B4) in the first direction. Accordingly, the ground pad 13A, 13B function as a shield between the first signal pad and the second signal pad to prevent electromagnetic field coupling between the signal pads, and thereby isolation characteristics can be improved.

In a direction toward a center of the dielectric substrate 11 in plan view, an extension part 131 extends (e.g., in the first direction) from the long side of the ground pad 13A between the respective ones of the signal pad members 14A1 to 14A4 included in the first signal pad. Similarly, in the direction toward the center of the dielectric substrate 11 in plan view, the extension part 131 extends (e.g., in the first direction) from the long side of the ground pad 13B between the respective ones of the signal pad members 14B1 to 14B4 included in the first signal pad.

In a direction oriented away from the center of the dielectric substrate 11 in plan view, an extension part 132 extends (e.g., in the first direction) from the long side of the ground pad 13A between the respective ones of the signal pad members 15A1 to 15A4 included in the second signal pad. Similarly, in the direction oriented away from the center of the dielectric substrate 11 in plan view, the extension part 132 extends (e.g., in the first direction) from the long side of the ground pad 13B between the respective ones of the signal pad members 15B1 to 15B4 included in the second signal pad.

The ground pad 13A, the extension part 131, and the extension part 132 are integrally formed, but they may be electrically coupled as separate members. The ground pad 13B, the extension part 131, and the extension part 132 are integrally formed, but they may be electrically coupled as separate members.

The extension part 131 and the extension part 132 extending from the ground pad 13A, 13B can prevent impedance mismatching of the transmission line 141 and the transmission line 151 at the mounting part of the connector 12A.

The extension parts 131 extending from the ground pad 13A and 13B can provide electrical isolation between the signal pad members 14A1 to 14A4 and between the signal pad members 14B1 to 14B4, and thereby isolation characteristics can be improved.

The extension parts 132 extending from the ground pads 13A and 13B can suppress coupling between the signal pad members 15A1 to 15A4 and between the signal pad members 15B1 to 15B4, and thereby isolation characteristics can be improved.

Note that a length of each of the extension parts 131 and 132 in the first direction may be equal to or less than a length of each of the first signal pad and the second signal pad. Accordingly, occurrence of unnecessary resonance between the extension part 131, 132 and the signal pad can be suppressed.

The length of the ground pad 13A (13B) in the second direction (longitudinal direction) is longer than the length of the connector 12A (12B) in the second direction (longitudinal direction). Accordingly, mounting strength in mounting the connector 12A, 12B can be improved, and mounting accuracy can be improved. Here, in mounting the connector 12A, 12B, solder is applied to the symmetrically shaped ground pad 13A (13B). Mounting accuracy of the connector 12A, 12B is improved by a self-alignment effect returning to a design center by surface tension of the melted solder.

Next, the connector 12A, 12B will be described. FIG. 5 is a diagram illustrating the connector 12A, 12B according to Embodiment 1. Part (A) of FIG. 5 is a front view of the connector 12A, 12B, and part (B) of FIG. 5 is a plan view of the connector 12A, 12B.

The connector 12A, 12B is a connector to transmit a radio-frequency signal from a substrate to another substrate. The connector 12A, 12B includes a main body part 121, a first conductor part 122, and a second conductor part 123. The main body part 121 includes an insulator member. The first conductor part 122 and the second conductor part 123 include conductor members.

The first conductor part 122 is electrically coupled to the ground pad 13A, 13B. The second conductor part 123 is electrically coupled to the first signal pad and the second signal pad.

In this way, in the transmission line structure 10 of Embodiment 1, the length of the ground pad 13A, 13B in the first direction in which the transmission line 141, 151 extends is shorter than the dimension of the connector 12A, 12B, and the contact area between the ground pad 13A, 13B and the connector 12A, 12B is small. Accordingly, when the transmission line structure 10 is bent, the force applied to the connection part between the ground pad 13A, 13B and the connector 12A, 12B can be reduced, and the transmission line structure 10 can be easily bent.

### Embodiment 2

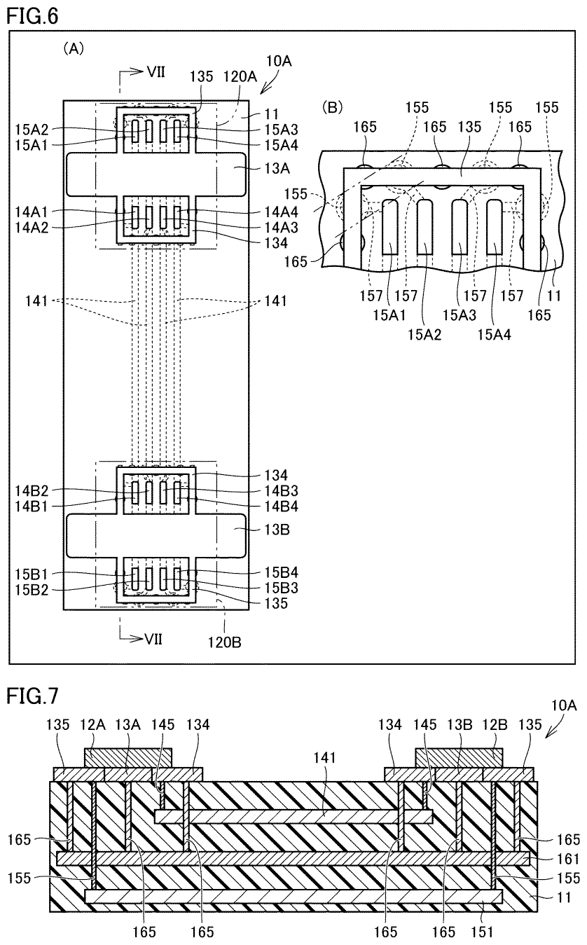

Next, a transmission line structure 10A according to Embodiment 2 will be described with reference to FIGS. 6 and 7. FIG. 6 is a plan view of the transmission line structure 10A according to Embodiment 2. Part (A) of FIG. 6 illustrates the entire transmission line structure 10A, and part (B) of FIG. 6 illustrates a partially enlarged part of the transmission line structure 10A. FIG. 7 is a partial sectional view taken along line VII-VII in FIG. 6.

The transmission line structure 10A according to Embodiment 2 has a partially different structure from the structure of the transmission line structure 10 according to Embodiment 1. Specifically, the transmission line structure 10A is different from the transmission line structure 10 in the shape of the extension part extending from the ground pad 13A, 13B, the position of the transmission line 141 in the thickness direction of the dielectric substrate 11, the position of the ground vias 165, and in that signal vias 145 coupled to the transmission line 141 are provided.

In the transmission line structure 10A, an extension part 134 extends from the long side of the ground pad 13A, 13B in such a manner as to surround the entire outer periphery of the first signal pad. In the transmission line structure 10A, an extension part 135 extends from the long side of the ground pad 13A, 13B in such a manner as to surround the entire outer periphery of the second signal pad.

In this way, by the extension part 134, 135 surrounding the entire outer peripheries of each signal pad, electromagnetic interference from the outside can be prevented, and electromagnetic compatibility (EMC) can be improved. The extension part 134 can suppress occurrence of unnecessary waves from the transmission line 141, and the extension part 135 can also suppress occurrence of unnecessary waves from the transmission line 151.

In the transmission line structure 10A, the position of the transmission line 141 in the thickness direction of the dielectric substrate 11 is closer to the ground electrode 161 than its position in the transmission line structure 10 (e.g., the transmission line 141 may be spaced apart from the first main surface). Accordingly, the transmission line 141 can be protected from the outside.

As illustrated in part (B) of FIG. 6 and FIG. 7, in the transmission line structure 10A, the ground vias 165 are electrically coupled to the extension part 135 at multiple positions. Similarly, the ground vias 165 are electrically coupled also to the extension part 134 at multiple positions.

As illustrated in part (B) of FIG. 6 and FIG. 7, the signal vias 155 provided to end portions of the respective ones of the multiple signal pad members 15A1 to 15A4 (15B1 to 15B4) included in the second signal pad are disposed at positions overlapping the extension part 135 when seen in plan view in a normal direction of the ground pad 13A (13B). Similarly, the signal vias 145 provided to end portions of the respective ones of the multiple signal pad members 14A1 to 14A4 (14B1 to 14B4) included in the first signal pad are disposed at positions overlapping the extension part 134 when seen in plan view in the normal direction of the ground pad 13A (13B).

Note that each of the signal pad members 14A1 to 14A4 (14B1 to 14B4) is electrically coupled to the signal via 145 (155) via a signal line 157. The signal via 145 (155) is disposed at a position not overlapping the extension part 134 (135) in the thickness direction of the dielectric substrate 11.

As illustrated in part (B) of FIG. 6 and FIG. 7, on the second signal pad side, the multiple ground vias 165 are at least partially disposed at positions connecting the respective ones of the signal vias 155 adjacent to each other (position indicated by a two-dot chain line in part (B) of FIG. 6). Similarly, on the first signal pad side, the multiple ground vias 165 are at least partially disposed at positions connecting the respective ones of the signal vias 145 adjacent to each other.

In this way, the ground vias 165 are disposed at positions surrounding the signal vias 145, 155 in a grid-like manner. Accordingly, coupling between the signal pad members 14A1 to 14A4 and between the signal pad members 14B1 to 14B4 can be suppressed, and thereby isolation characteristics can be improved. The grid-like arrangement of the ground vias 165 can suppress occurrence of unnecessary waves from the transmission line 141 and can also suppress occurrence of unnecessary waves from the transmission line 151.

### Embodiment 3

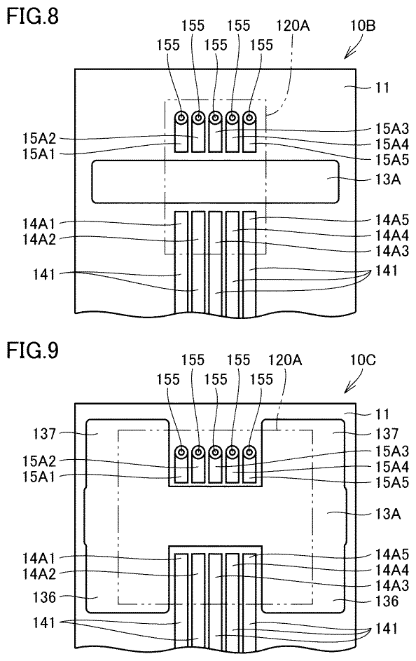

Next, a transmission line structure 10B according to Embodiment 3 will be described with reference to FIG. 8. FIG. 8 is a plan view of the transmission line structure 10B according to Embodiment 3. FIG. 8 illustrates a partially enlarged part of the transmission line structure 10B.

The transmission line structure 10B according to Embodiment 3 is different from the transmission line structure 10 according to Embodiment 1 in that the extension parts 131 and 132 are not provided and signal pad members 14A5 and 15A5 are added.

As illustrated in FIG. 8, the extension parts 131 and 132 are not necessarily provided, and the number of signal pad members 14A1 to 14A5 (15A1 to 15A5) may be appropriately changed. That is, the number of transmission lines 141 (151) connected to the signal pad members 14A1 to 14A5 (15A1 to 15A5) may be appropriately changed.

### Embodiment 4

Next, a transmission line structure 10C according to Embodiment 4 will be described with reference to FIG. 9. FIG. 9 is a plan view of the transmission line structure 10C according to Embodiment 4. FIG. 9 illustrates a partially enlarged part of the transmission line structure 10C.

The transmission line structure 10C according to Embodiment 4 is different from the transmission line structure 10B according to Embodiment 3 in the shape of the extension part extending from the ground pad 13A, 13B.

As illustrated in FIG. 9, the transmission line structure 10C includes protrusion parts 136 and 137 at both end portions of the ground pad 13A (13B) in the second direction (longitudinal direction) and protruding in the first direction (transverse direction). When seen in plan view in the normal direction of the ground pad 13A (13B), a shape including the ground pad 13A (13B) and the protrusion parts 136 and 137 is an approximately H-shape.

Accordingly, in a range of the outer edge 120A where the connector 12A is disposed, a ratio occupied by the ground pad 13A and the protrusion parts 136 and 137 increases, which can improve mounting strength of the connector 12A. Since the ground pad 13A and the protrusion parts 136 and 137 are symmetrical in the first direction and the second direction, self-alignment can be improved. The transmission line structure 10C can similarly improve mounting strength and self-alignment on the connector 12B side.

Note that the shape formed with the protrusion parts 136 and 137 may be any shape other than an approximately H-shape as long as it is symmetrical in the first direction and the second direction.

### Modifications

In the embodiments described above, the ground pad 13A (13B) may be divided into a plurality of parts as long as it has a rectangular shape. The ground pad 13A (13B) may have a rectangular shape with rounded corners to be an ellipse-like shape.

In the embodiments described above, the substrate coupled to the connector 12A, 12B of the transmission line structure 10 may be a substrate other than the substrate used for an antenna such as the antenna device 190A, 190B.

The embodiments described above are the case where the connector 12A is provided to the ground pad 13A and the connector 12B is provided to the ground pad 13B at the respective ones of both ends of the transmission line structure 10. However, the transmission line structure 10 may have a structure in which a connector is provided to one end and something other than a connector is provided to the other end. For example, the transmission line structure 10 may have a structure in which a connector is provided to one end and a patch antenna is provided to the other end. A signal may be transmitted to the patch antenna to radiate radio waves.

### <Modes>

(1) A transmission line structure according to the present disclosure includes a dielectric substrate in a flat-plate shape including a first main surface and a second main surface opposed to the first main surface; a ground electrode disposed between the first main surface and the second main surface; a first transmission line disposed closer to the first main surface with respect to the ground electrode and extending in a first direction; a ground pad provided to the first main surface; a first signal pad coupled to an end portion of the first transmission line at the first main surface; at least one interlayer connector disposed inside the dielectric substrate and coupled to the ground electrode and the ground pad; and a connector coupled to the ground pad and the first signal pad on a side of the first main surface. The ground pad has a rectangular shape including a long side in a second direction approximately perpendicular to the first direction and a short side in the first direction. A length of the ground pad in the first direction is shorter than a dimension of the connector in the first direction.

According to the transmission line structure of the present disclosure, when the transmission line structure is bent, force applied to the connection part between the ground pad and the connector can be reduced, and the transmission line structure can be easily bent.

(2) The transmission line structure according to (1) further includes a second transmission line disposed closer to the second main surface with respect to the ground electrode. A frequency band of a signal transmitted to the first transmission line is higher than a frequency band of a signal transmitted to the second transmission line.

According to the transmission line structure of the present disclosure, since a signal in a higher frequency band has larger loss due to distance than a signal in a lower frequency band, the first transmission line having a higher signal frequency band than the second transmission line can be disposed closer to the connector. Accordingly, signal loss can be reduced.

(3) The transmission line structure according to (2) further includes a second signal pad coupled to an end portion of the second transmission line at the first main surface. The ground pad is disposed between the first signal pad and the second signal pad.

According to the transmission line structure of the present disclosure, the ground pad functions as a shield between the first signal pad and the second signal pad to prevent electromagnetic field coupling between the signal pads, and thereby isolation characteristics can be improved.

(4) In the transmission line structure according to any one of (1) to (3), the first transmission line is provided to the first main surface.

According to the transmission line structure of the present disclosure, the first transmission line and the connector are directly connected to each other, and thereby impedance matching with a member coupled to the first transmission line can be easier.

(5) In the transmission line structure according to any one of (1) to (4), a length of the ground pad in the second direction is longer than a dimension of the connector in the second direction.

According to the transmission line structure of the present disclosure, mounting strength in mounting the connector can be improved, and mounting accuracy can be improved.

(6) In the transmission line structure according to any one of (3) to (5), each of the first signal pad and the second signal pad includes multiple signal pad members. The transmission line structure further includes a first extension part extending from the long side of the ground pad between respective ones of the signal pad members included in each of the first signal pad and the second signal pad.

According to the transmission line structure of the present disclosure, the first extension part can prevent impedance mismatching of the first transmission line and the second transmission line at the mounting part of the connector, and can improve isolation characteristics.

(7) The transmission line structure according to any one of (3) to (5) further includes a second extension part coupled to the ground pad and provided to surround an entire outer periphery of each of the first signal pad and the second signal pad.

According to the transmission line structure of the present disclosure, electromagnetic interference from the outside can be prevented, and electromagnetic compatibility (EMC) can be improved.

(8) In the transmission line structure according to (7), the at least one interlayer connector includes multiple interlayer connectors. Each of the first signal pad and the second signal pad includes multiple signal pad members. The multiple interlayer connectors are coupled to the second extension part at multiple positions on the side of the first main surface. Signal vias provided to end portions of respective ones of the multiple signal pad members included in each of the first signal pad and the second signal pad are disposed at positions overlapping the second extension part when seen in plan view in a normal direction of the ground pad. The multiple interlayer connectors are at least partially disposed at positions connecting the respective ones of the signal vias adjacent to each other.

According to the transmission line structure of the present disclosure, electrical isolation can be provided between the signal pad members, and thereby isolation characteristics can be improved. The grid-like arrangement of the interlayer connectors can suppress occurrence of unnecessary waves from the first transmission line and can also suppress occurrence of unnecessary waves from the second transmission line.

(9) The transmission line structure according to any one of (1) to (8) further includes protrusion parts at both end portions of the ground pad in the second direction and protruding in the first direction.

According to the transmission line structure of the present disclosure, mounting strength of the connector can be improved, and self-alignment can be improved.

(10) In the transmission line structure according to (9), a shape including the ground pad and the protrusion parts is an approximately H-shape when seen in plan view in a normal direction of the ground pad.

According to the transmission line structure of the present disclosure, mounting strength of the connector can be improved, and self-alignment can be improved.

(11) An antenna module according to the present disclosure includes: the transmission line structure according to any one of (1) to (10); and an antenna substrate coupled to the transmission line structure via the connector and including a radiation electrode, the connector being provided to the transmission line structure.

By way of summation and review, according to an aspect of the present disclosure, the ground pad has a rectangular shape including the long side in the second direction approximately perpendicular to the first direction in which the first transmission line extends (e.g., so a longitudinal direction of the ground pad is approximately perpendicular to a longitudinal direction of the first transmission line). The length of the ground pad in the first direction (i.e., of the short side of the rectangular shape) is shorter than a length of the connector in the first direction. That is, in the transmission line structure, the length of the ground pad is shorter than the dimension of the connector in the first direction in which the first transmission line extends, and a contact area between the ground pad and the connector is small. Accordingly, when the transmission line structure is bent, force applied to a connection part between the ground pad and the connector can be reduced, and the transmission line structure can be easily bent.

According to the antenna module of the present disclosure, the antenna module can include the transmission line structure that can be easily bent.

The embodiments disclosed herein should be construed to be illustrative and not restrictive in all respects. The scope of the present disclosure is shown not by the above description but by the claims, and is intended to include all changes within the meaning and scope equivalent to the claims.

### REFERENCE SIGNS LIST

10, 10A, 10B, 10C transmission line structure
11 dielectric substrate
12A, 12B connector
13A, 13B ground pad
14A1-14A4, 14B1-14B5, 15A1-15A4, 15B1-15B4 signal pad member
20 protection member
100 antenna module
120A, 120B outer edge
121 main body part
122 first conductor part
123 second conductor part
131, 132, 134, 135 extension part
136, 137 protrusion part
141, 151 transmission line
145, 155 signal via
157 signal line
161, 170A, 170B, 181, 251 ground electrode
165 ground via
180 connection member
190, 190A, 190B antenna device
191, 191A1-191A4, 191B-191B4 radiation electrode
250 motherboard

1. A transmission line structure, comprising:
a dielectric substrate having a flat-plate shape, the dielectric substrate including a first main surface and a second main surface opposed to the first main surface;
a ground electrode between the first main surface and the second main surface;
a first transmission line disposed closer to the first main surface than to the ground electrode, the first transmission line extending in a first direction;
a ground pad provided to the first main surface;
a first signal coupled to an end portion of the first transmission line, the first signal pad being at the first main surface;
at least one interlayer connector inside the dielectric substrate, the at least one interlayer connector being coupled to the ground electrode and the ground pad; and
a connector on the first main surface, the connector being coupled to the ground pad and the first signal pad,
wherein the ground pad has a rectangular shape including a long side and a short side, the long side extending in a second direction approximately perpendicular to the first direction, and the short side extending in the first direction, and
wherein a length of the ground pad in the first direction is shorter than a length of the connector in the first direction.

2. The transmission line structure according to claim 1, further comprising a second transmission line disposed closer to the second main surface than to the ground electrode, wherein
a frequency band of a signal transmitted to the first transmission line is higher than a frequency band of a signal transmitted to the second transmission line.

3. The transmission line structure according to claim 2, further comprising a second signal pad coupled to an end portion of the second transmission line, the second signal pad being at the first main surface, wherein
the ground pad is between the first signal pad and the second signal pad.

4. The transmission line structure according to claim 3, wherein:
each of the first signal pad and the second signal pad includes multiple signal pad members, and
the transmission line structure further comprises a first extension part extending from the long side of the ground pad between respective ones of the signal pad members included in each of the first signal pad and the second signal pad.

5. The transmission line structure according to claim 3, further comprising a second extension part coupled to the ground pad and surrounding an entire outer periphery of each of the first signal pad and the second signal pad.

6. The transmission line structure according to claim 5, wherein:
the at least one interlayer connector includes multiple interlayer connectors,
each of the first signal pad and the second signal pad includes multiple signal pad members,
the multiple interlayer connectors are coupled to the second extension part at multiple positions on the first main surface,
signal vias at end portions of respective ones of the multiple signal pad members included in each of the first signal pad and the second signal pad are at positions overlapping the second extension part when seen in plan view in a normal direction of the ground pad, and
the multiple interlayer connectors are at least partially at positions connecting respective ones of the signal vias adjacent to each other.

7. The transmission line structure according to claim 1, wherein the first transmission line is provided to the first main surface.

8. The transmission line structure according to claim 1, wherein a length of the ground pad in the second direction is longer than a length of the connector in the second direction.

9. The transmission line structure according to claim 1, further comprising protrusion parts at opposite end portions of the ground pad in the second direction, the protrusion parts protruding in the first direction.

10. The transmission line structure according to claim 9, wherein a combined structure of the ground pad and the protrusion parts has an approximately H-shape when seen in plan view in a normal direction of the ground pad.

11. The transmission line structure according to claim 1, wherein the ground pad and the connector are stacked along a normal direction with respect to the first transmission line.

12. The transmission line structure according to claim 1, wherein first main surfaces of the ground pad and the first signal pad face a same direction and are coplanar with each other.

13. An antenna module, comprising:
the transmission line structure according to claim 1; and
an antenna substrate coupled to the transmission line structure via the connector and including a radiation electrode, the connector being in the transmission line structure.

14. The antenna module according to claim 1, wherein the transmission line structure is in a bent state, the transmission line structure overlapping two different surfaces that are perpendicular to each other, and the ground pad and the connector being stacked along a normal direction with respect to the first transmission line.
